(19) United States
(12) Patent Application Publication
(10) Pub. No.: US 2015/0053234 A1
(43) Pub. Date: Feb. 26, 2015

(54) METHOD FOR CLEANING SEMICONDUCTOR WAFER

(71) Applicant: SHIN-ETSU HANDOTAI CO., LTD., Tokyo (JP)

(72) Inventors: Tatsuo Abe, Shirakawa (JP); Hitoshi Kabasawa, Annaka (JP)

(73) Assignee: SHIN-ETSU HANDOTAI CO., LTD., Tokyo (JP)

(21) Appl. No.: 14/390,655

(22) PCT Filed: Apr. 18, 2013
(86) PCT No.: PCT/JP2013/002610

§ 371 Date: Oct. 3, 2014

(30) Foreign Application Priority Data
May 18, 2012 (JP) 2012-114944

(51) Int. Cl. H01L 21/67; H01L 21/02

(52) U.S. Cl. CPC H01L 21/67057; H01L 21/02052
USPC 134/2

(57) ABSTRACT

The present invention is directed to a method for cleaning a semiconductor wafer which comprises filling a cleaning solution containing ammonia and aqueous hydrogen peroxide in a cleaning tank comprising a synthetic quartz material with an average Al concentration of 1 ppb or less, immersing the above-mentioned semiconductor wafer in the above-mentioned cleaning solution, and cleaning the above-mentioned semiconductor wafer so that a surface etching rate of the above-mentioned synthetic quartz by the above-mentioned cleaning solution becomes 0.3 nm/min or less, and according to this method, a cleaning method which can maintain the Al concentration in the ammonia and per-water cleaning solution to a low concentration and can improve surface cleanliness of the semiconductor wafer is provided.

### TECHNICAL FIELD

The present invention relates to a method for cleaning a semiconductor wafer.

### BACKGROUND ART

As a method for cleaning a semiconductor wafer, a mixed liquid containing ammonia and aqueous hydrogen peroxide (hereinafter also referred to as “per-water”) has generally been used as a cleaning solution. As a cleaning flow of the semiconductor wafer in this case, there may be mentioned, for example, ammonia and per-water cleaning→pure water rinsing→hydrochloric acid and per-water cleaning→pure water rinsing→drying. In this cleaning method, organic substances and particles attached to the surface are removed by the first ammonia and per-water cleaning solution, the chemicals are washed away by the pure water rinsing, then, metal impurities are removed in the next hydrochloric acid and per-water cleaning solution, and chemicals are again washed away by the pure water rinsing and drying is carried out.

In general, the cleaning solution to be used for cleaning of a semiconductor wafer is used by heating at 60° C. to 80° C. in many cases for heightening the cleaning effects. Therefore, a circulation filtration system is attached to a cleaning tank, and temperature control of the cleaning solution by a heater is carried out simultaneously with removal of the particles. There is also a case where the concentration of the chemical liquid is controlled constantly to prevent from lowering of the cleaning solution due to evaporation of the chemicals contained in the cleaning solution. There is further a case where ultrasonic wave cleaning is used in combination to improve removal power of the particles.

The cleaning solution to be used in a method for cleaning a semiconductor wafer also directly affects the quality of cleanliness of the semiconductor wafer, so that the particles in the cleaning solution or the concentration of metal impurities in the cleaning solution are strictly controlled. Also, high quality chemicals in which particles and impurities are reduced to the limit is used since the chemicals contained in the cleaning solution also directly affect the quality of cleanliness of the semiconductor wafer similarly.

### CITATION LIST

### Patent Literature

Patent Document 1:Japanese Unexamined Patent publication (Kokai) No. 2005-322714

### SUMMARY OF INVENTION

### Technical Problem

Ammonia and per-water cleaning to be used in the cleaning process of the semiconductor wafer is used mainly for removal of the particles, and there is a problem that metal impurities are likely remained on the surface of the semiconductor wafer. In particular, a material which becomes the problem as metal impurities is Al which is likely incorporated into the oxide film. Al is contained in natural quartz used as a cleaning tank quartz material about 10 ppmw, and the Al is eluted into the cleaning solution by etching of the quartz surface with ammonia and per-water cleaning to contaminate the surface of the semiconductor wafer.

Thus, when a semiconductor wafer with higher surface cleanliness is required, a synthetic quartz cleaning tank is sometimes used for reducing Al contamination of the surface (see Patent Document 1). However, even when such a synthetic quartz tank is used, metal contamination including Al cannot be avoided in the welding and heat treatment at the time of manufacturing the quartz tank, so that it is not possible to eliminate the Al contamination from the quartz cleaning tank.

The present invention has been accomplished in view of the above-mentioned problems, and an object thereof is to provide a cleaning method which can maintain an Al concentration in the ammonia and per-water cleaning solution to a low concentration, and can improve the surface cleanliness of the semiconductor wafer.

### Solution to Problem

To accomplish the above-mentioned objects, the present invention is to provide a method for cleaning a semiconductor wafer which comprises filling a cleaning solution containing ammonia and aqueous hydrogen peroxide in a cleaning tank comprising a synthetic quartz material with an average Al concentration of 1 ppb or less, immersing the above-mentioned semiconductor wafer in the above-mentioned cleaning solution, and cleaning the above-mentioned semiconductor wafer so that a surface etching rate of the above-mentioned synthetic quartz by the above-mentioned cleaning solution becomes 0.3 nm/min or less.

Thus, by cleaning the semiconductor wafer using a high purity synthetic quartz material as well as making a surface etching rate of synthetic quartz 0.3 nm/min or less, a surface Al concentration of the semiconductor wafer after ammonia and per-water cleaning becomes 1×10¹⁰ atoms/cm² or lower, whereby surface cleanliness of the semiconductor wafer is improved. Further, it is also possible to omit acid cleaning of the semiconductor wafer which had been necessary for making the surface Al concentration of the semiconductor wafer 1×10¹⁰ atoms/cm² or lower.

At this time, it is preferred to carry out cleaning of the above-mentioned semiconductor wafer while constantly controlling the respective concentrations of the ammonia and the aqueous hydrogen peroxide in the above-mentioned cleaning solution by a circulation filtering apparatus which is to carry out filtration and heating at a constant temperature by circulating the above-mentioned cleaning solution.

Thus, by cleaning the semiconductor wafer while constantly controlling the respective concentrations of ammonia and aqueous hydrogen peroxide in the cleaning solution, the surface etching rate of the synthetic quartz can be surely controlled to the predetermined value, and the cleaning effect of the semiconductor wafer can be heightened.

### Advantageous Effects of Invention

As mentioned above, according to the present invention, it is possible to make the surface Al concentration of the semiconductor wafer after ammonia and per-water cleaning 1×10¹⁰ atoms/cm² or lower, so that surface cleanliness of the semiconductor wafer can be improved, and acid cleaning to make the surface Al concentration of the semiconductor wafer 1×10¹⁰ atoms/cm² or lower can be omitted, whereby a semiconductor wafer having high cleanliness can be obtained with a lower cost and a shorter time.

### BRIEF DESCRIPTION OF DRAWINGS

FIG. 1 is a flow chart of the treatment applied to a semiconductor wafer for examining a surface metal impurity (Al) concentration of the semiconductor wafer before cleaning experiment in Examples and Comparative Examples;

FIG. 2 is a cleaning flow chart of a cleaning experiment in Examples and Comparative Examples; and

FIG. 3 is an apparatus which can perform the method for cleaning a semiconductor wafer in the present invention.

### DESCRIPTION OF EMBODIMENTS

In the following, the present invention is explained in more detail by referring to the drawings as one example of the embodiments, but the present invention is not limited by these.

FIG. 3 is a schematic drawing showing one example of apparatuses for performing the method for cleaning a semiconductor wafer of the present invention. In FIG. 3, a cleaning solution 3 is filled in a cleaning tank 2, a semiconductor wafer 1 is immersed in the cleaning solution 3 to clean the semiconductor wafer 1. At that time, by circulating the cleaning solution 3 through a filtering apparatus 5, each concentration of the chemicals in the cleaning solution is controlled constantly. Further, a liquid temperature of the cleaning solution 3 is controlled constantly by a heating apparatus 4 for heating the cleaning solution 3 in the cleaning tank 2. In this cleaning apparatus 6, the cleaning tank 2 is formed by synthetic quartz with an average Al concentration of 1 ppb or less.

By using such an apparatus, the present invention is a method for cleaning a semiconductor wafer which comprises filling a cleaning solution containing ammonia and aqueous hydrogen peroxide in a cleaning tank comprising a synthetic quartz material with an average Al concentration of 1 ppb or less, immersing a semiconductor wafer in the cleaning solution, and cleaning the semiconductor wafer so that a surface etching rate of the synthetic quartz by the cleaning solution becomes 0.3 nm/min or less.

Thus, by cleaning the semiconductor wafer using high purity synthetic quartz as well as making a surface etching rate of synthetic quartz 0.3 nm/min or less, a surface Al concentration of the semiconductor wafer after ammonia and per-water cleaning becomes 1×10¹⁰ atoms/cm² or lower, whereby surface cleanliness of the semiconductor wafer is improved. Further, it is also possible to omit acid cleaning of the semiconductor wafer which had been necessary for making the surface Al concentration of the semiconductor wafer 1×10¹⁰ atoms/cm² or lower, whereby a semiconductor wafer having high cleanliness can be obtained with a lower cost and with a shorter time.

The acid cleaning is a cleaning using an acidic chemical liquid and has been widely used for wafer cleaning in manufacturing an IC, and in the method for cleaning a semiconductor wafer of the present invention, the surface Al concentration of the semiconductor wafer after cleaning can be made 1×10¹⁰ atoms/cm² or lower as mentioned above, so that the acid cleaning of the semiconductor wafer can be omitted. However, in the present invention, the acid cleaning may be carried out, if necessary, and such a case is not intended to exclude from the present invention.

It is also preferred that the cleaning solution 3 is filtered through a filtering apparatus 5 by circulation using the cleaning apparatus 6 as shown in FIG. 3, and the cleaning solution 3 in a cleaning tank 2 comprising synthetic quartz is further heated at a constant temperature by a heating apparatus 4, whereby the semiconductor wafer 1 is cleaned while constantly controlling the respective concentrations of ammonia and aqueous hydrogen peroxide in the cleaning solution 3.

Thus, by cleaning the semiconductor wafer while constantly controlling the respective concentrations of ammonia and aqueous hydrogen peroxide and the liquid temperature of the cleaning solution, a rate of the surface of the cleaning tank comprising synthetic quartz to be etched by the cleaning solution can be surely made 0.3 nm/min or less, so that the cleaning effect of the semiconductor wafer can be heightened.

Incidentally, the semiconductor wafer to be cleaned in the present invention is not particularly limited, and in addition to the silicon wafer, an elemental semiconductor such as germanium or a compound semiconductor such as GaAs and InP may be also used.

### EXAMPLE

In the following, the present invention is explained in more detail by referring to Examples and Comparative Examples, but the present invention is not limited by these.

### Example 1

A wafer of clean silicon single crystal having a diameter of 300 mm both surfaces of which had been finished with mirror surfaces was prepared. This silicon wafer was so treated, as shown in FIG. 1, that ammonia and per-water cleaning was carried out, then, cleaning by diluted hydrofluoric acid was carried out continuously, further a treatment with ozonated water was applied to form a clean oxide film onto the silicon wafer surface, and drying thereof was carried out.

Thereafter, to examine the surface metal impurity (Al) concentration of the clean silicon wafer, the surface metal impurity (Al) of the silicon wafer was recovered by hydrofluoric acid, and the recovered liquid was quantitatively analyzed by an ICP-MS analysis apparatus. As a result of the analysis, the surface metal impurity (Al) concentration of the silicon wafer before the experiment was all N.D. (not detected, or the detection limit or less).

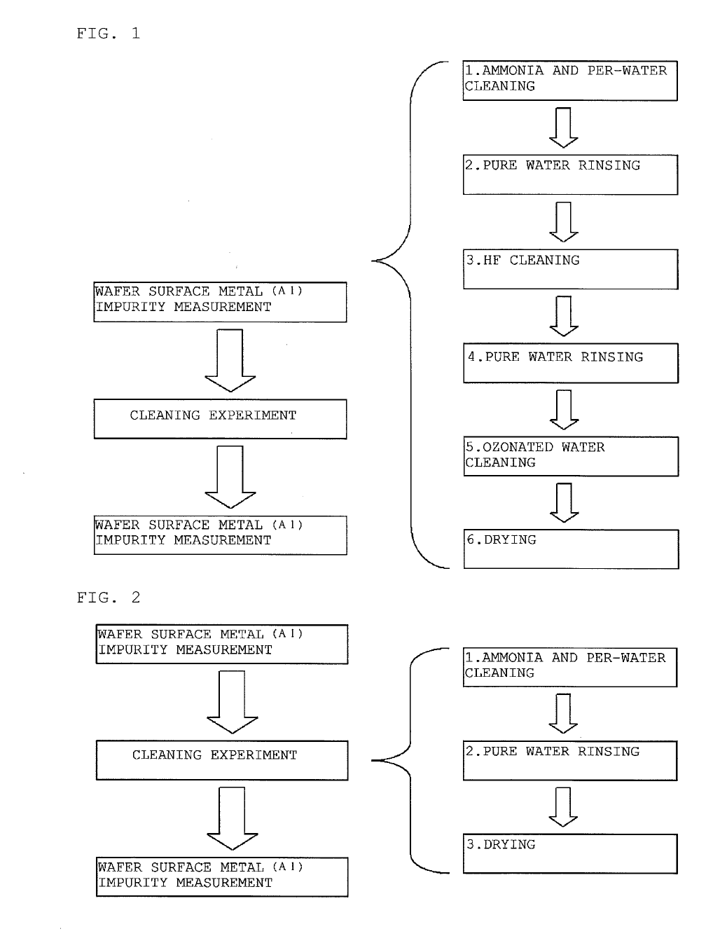

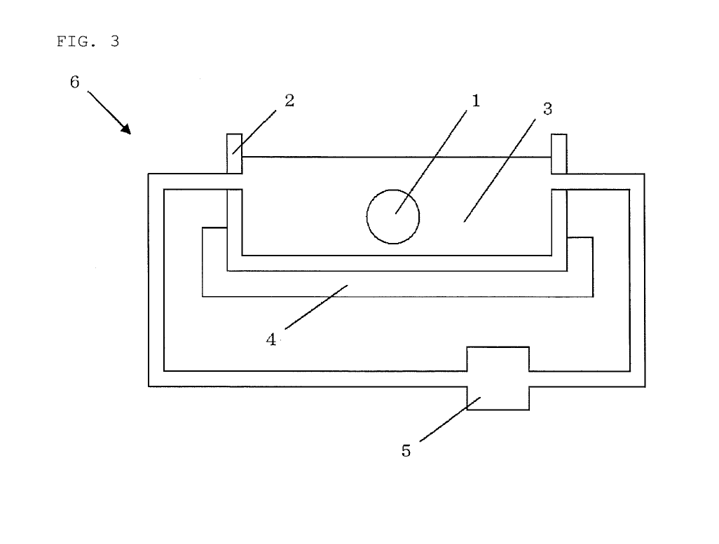

Next, a cleaning experiment of the silicon wafer using the synthetic quartz cleaning tank was carried out. This cleaning experiment is, as shown in FIG. 2, to carry out firstly by immersing the silicon wafer in ammonia and per-water cleaning solution filled in the synthetic quartz cleaning tank to clean the same. At this time, as the cleaning conditions, the chemical liquid composition (mixing ratio) of ammonia and per-water cleaning solution was made ammonia:per-water:pure water=1:1:10. Also, the cleaning solution temperature was set at 50° C., so that the etching rate of the synthetic quartz by the ammonia and per-water cleaning solution during the cleaning was made 0.3 nm/min. Incidentally, the ammonia and per-water cleaning was carried out for 5 minutes after subjecting to temperature control and circulation filtration for 4 hours after preparing the above-mentioned cleaning solution, and the synthetic quartz cleaning tank with an average Al concentration therein of 0.5 ppb was used.

Thereafter, the silicon wafer to which the ammonia and per-water cleaning had been applied was subjected to pure water rinsing, and the silicon wafer which had been subjected to the pure water rinsing was further dried.

After completion of the above-mentioned cleaning experiment, an Al concentration contained in the quartz of the synthetic quartz tank was analyzed by taking out an analytical sample from the synthetic quartz tank, dissolved in hydrofluoric acid, and then, measured by ICP-MS whereby the surface metal impurity (Al) concentration of the silicon wafer was calculated.

### Example 2

A cleaning experiment was carried out in the same manner as in Example 1 except that a cleaning solution temperature at the cleaning experiment of the silicon wafer by the ammonia and per-water cleaning solution was made 40° C., so that the etching rate of the synthetic quartz by the ammonia and per-water cleaning solution during the cleaning was made 0.2 nm/min, and the surface metal impurity (Al) concentration of the silicon wafer of the synthetic quartz tank after completion of the experiment was calculated.

### Example 3

A cleaning experiment was carried out in the same manner as in Example 1 except for using a synthetic quartz tank having an average Al concentration of 1.0 ppb as a cleaning tank at the time of the cleaning experiment of the silicon wafer by the ammonia and per-water cleaning solution, and the surface metal impurity (Al) concentration of the silicon wafer after completion of the experiment was calculated.

### Comparative Example 1

A cleaning experiment was carried out in the same manner as in Example 1 except that a natural quartz tank having an average Al concentration of 10 ppm was used as an ammonia and per-water cleaning tank at the time of the cleaning experiment of the silicon wafer by the ammonia and per-water cleaning solution, and a cleaning solution temperature was made 80° C., so that the etching rate of the synthetic quartz by the ammonia and per-water cleaning solution during the cleaning was made 0.7 nm/min, and the silicon wafer surface metal impurity (Al) concentration after completion of the experiment was calculated.

### Comparative Example 2

A cleaning experiment was carried out in the same manner as in Comparative Example 1 except for using a synthetic quartz tank having an average Al concentration of 2.0 ppb as an ammonia and per-water cleaning tank at the time of the cleaning experiment of the silicon wafer by the ammonia and per-water cleaning solution, and the silicon wafer surface metal impurity (Al) concentration after completion of the experiment was calculated.

### Comparative Example 3

A cleaning experiment was carried out in the same manner as in Comparative Example 2 except that a cleaning solution temperature was made 50° C. at the time of the cleaning experiment of the silicon wafer by the ammonia and per-water cleaning solution, so that the etching rate of the synthetic quartz by the ammonia and per-water cleaning solution during the cleaning was made 0.3 nm/min, and the silicon wafer surface metal impurity (Al) concentration after completion of the experiment was calculated.

In the following, cleaning conditions of the silicon wafer and the results of the analyses of the wafer surface metal impurity (Al) concentration after cleaning of the silicon wafer in Examples 1 to 3 and Comparative Examples 1 to 3 were summarized in Tables 1 and 2, respectively.

TABLE 1

| | Quartz tank material | Ammonia and per-water |
|---|---|---|
| | (average Al | cleaning |
| Conditions | concentration) | (SiO₂ etching rate) |
| Comparative | Natural quartz | SiO₂ etching rate = |
| Example 1 | (10,000 ppb = 10 ppm) | 0.7 nm/min |
| | | NH₄OH:H₂O₂:H₂O = 1:1:10 |
| | | Temperature = 80° C. |
| Comparative | Synthetic quartz | SiO₂ etching rate = |
| Example 2 | (2.0 ppb) | 0.7 nm/min |
| | | NH₄OH:H₂O₂:H₂O = 1:1:10 |
| | | Temperature = 80° C. |
| Comparative | Synthetic quartz | SiO₂ etching rate = |
| Example 3 | (2.0 ppb) | 0.3 nm/min |
| | | NH₄OH:H₂O₂:H₂O = 1:1:10 |
| | | Temperature = 50° C. |
| Example 1 | Synthetic quartz | SiO₂ etching rate = |
| | (0.5 ppb) | 0.3 nm/min |
| | | NH₄OH:H₂O₂:H₂O = 1:1:10 |
| | | Temperature = 50° C. |
| Example 2 | Synthetic quartz | SiO₂ etching rate = |
| | (0.5 ppb) | 0.2 nm/min |
| | | NH₄OH:H₂O₂:H₂O = 1:1:10 |
| | | Temperature = 40° C. |
| Example 3 | Synthetic quartz | SiO₂ etching rate = |
| | (1.0 ppb) | 0.3 nm/min |
| | | NH₄OH:H₂O₂:H₂O = 1:1:10 |
| | | Temperature = 50° C. |

TABLE 2

| | Wafer surface metal impurity |
|---|---|
| Conditions | (Al concentration) |
| Comparative | 22.1 × 10¹⁰ atoms/cm² |
| Example 1 | |
| Comparative | 3.9 × 10¹⁰ atoms/cm² |
| Example 2 | |
| Comparative | 1.9 × 10¹⁰ atoms/cm² |
| Example 3 | |
| Example 1 | 0.6 × 10¹⁰ atoms/cm² |
| Example 2 | 0.4 × 10¹⁰ atoms/cm² |
| Example 3 | 0.9 × 10¹⁰ atoms/cm² |

From the results of Examples 1 to 3 mentioned above, it could be understood that the surface Al concentration of the semiconductor wafer after the ammonia and per-water cleaning can be made 1×10¹° atoms/cm² or lower because the semiconductor wafer is cleaned by filling a cleaning solution containing ammonia and per-water in a cleaning tank comprising a synthetic quartz material with an average Al concentration of 1 ppb or less when the semiconductor wafer is cleaned, immersing the semiconductor wafer in the cleaning solution, and making the conditions that a surface etching rate of the synthetic quartz by the cleaning solution becomes 0.3 nm/min or less.

On the other hand, in Comparative Examples 1 and 2, the surface Al concentration of the semiconductor wafer after the ammonia and per-water cleaning could not be made 1×10¹⁰ atoms/cm² or lower because the semiconductor wafer is cleaned by filling a cleaning solution containing ammonia and per-water in a cleaning tank comprising a quartz material (Comparative Example 1 is natural quartz, and Comparative Example 2 is synthetic quartz) with an average Al concentration greater than 1 ppb when the semiconductor wafer is cleaned, immersing the semiconductor wafer in the cleaning solution, and cleaning the semiconductor wafer with a surface etching rate of the quartz by the cleaning solution greater than 0.3 nm/min.

Also, in Comparative Example 3, the surface Al concentration of the semiconductor wafer after the ammonia and per-water cleaning could not be made 1×10¹⁰ atoms/cm² or lower similarly as in Comparative Examples 1 and 2, because a cleaning tank comprising a synthetic quartz material with an average Al concentration greater than 1 ppb was used while the semiconductor wafer is cleaned by the cleaning solution containing ammonia and per-water so that the surface etching rate of the synthetic quartz became 0.3 nm/min.

Incidentally, in Examples 1 to 3 and Comparative Examples 1 to 3, the etching rate of the quartz tank is changed by a temperature of the cleaning solution when the ammonia and per-water cleaning is carried out, but the etching rate of the quartz tank can be similarly changed by changing a composition due to a mixing ratio of ammonia and per-water contained in the cleaning solution.

It must be stated here that the present invention is not restricted to the embodiments shown by Examples. The embodiments shown by Examples are merely examples so that any embodiments composed of substantially the same technical concept as disclosed in the claims of the present invention and expressing a similar effect are included in the technical scope of the present invention.

1. A method for cleaning a semiconductor wafer which comprises filling a cleaning solution containing ammonia and aqueous hydrogen peroxide in a cleaning tank comprising a synthetic quartz material with an average Al concentration of 1 ppb or less, immersing the semiconductor wafer in the cleaning solution, and cleaning the semiconductor wafer so that a surface etching rate of the synthetic quartz by the cleaning solution becomes 0.3 nm/min or less.

2. The method for cleaning a semiconductor wafer according to claim 1, wherein the semiconductor wafer is cleaned by constantly controlling the respective concentrations of the ammonia and the aqueous hydrogen peroxide in the cleaning solution by a circulation filtering apparatus which is to carry out filtration and heating at a constant temperature by circulating the cleaning solution.
